(19) United States
(12) Patent Application Publication
(10) Pub. No.: US 2026/0026052 A1
(43) Pub. Date: Jan. 22, 2026

(54) SEMICONDUCTOR STRUCTURES AND METHODS OF FORMING THE SAME

(71) Applicant: Taiwan Semiconductor Manufacturing Company, Ltd., Hsin-Chu (TW)

(72) Inventors: Chia Lin Yeh, New Taipei City (TW); Guan-Xuan Chen, Taoyuan (TW); Po-Chuan Wang, Taipei City (TW); Yi-Chen Wang, Hsinchu (TW); Guang-Hong Zheng, Hsinchu City (TW); Fang-Yu Lin, Hsinchu (TW); Jyun-De Wu, Hsinchu (TW); Ching-Yang Chu, Hsinchu City (TW); Chao-Cheng Chen, Hsinchu (TW); Chih-Yuan Ting, Taipei City (TW); Sheng-Liang Pan, Hsinchu (TW); Yuan-Tien Tu, Hsinchu (TW); Chia-Yang Hung, Kaohsiung City (TW)

(21) Appl. No.: 18/778,598

(22) Filed: Jul. 19, 2024

(51) Int. Cl. H01L 29/06; H01L 21/28; H01L 21/311; H01L 21/768; H01L 23/522; H01L 29/417; H01L 29/423; H01L 29/66; H01L 29/78

(52) U.S. Cl. CPC H10D 62/102; H01L 21/28229; H01L 21/31116; H01L 21/31144; H01L 21/76816; H01L 21/76831; H01L 23/5226; H10D 30/6219; H10D 30/6729; H10D 30/024; H10D 30/62; H10D 30/6735; H10D 62/121

(57) ABSTRACT

An exemplary method according to the present disclosure includes forming a first dielectric layer over a first conductive feature, forming a second dielectric layer over the first dielectric layer, forming a patterned mask over the second dielectric layer, performing a first etching process to form a trench extending through the first dielectric layer and the second dielectric layer to expose a top surface of the first conductive feature, where etchant of the first etching process modifies a portion of the first dielectric layer exposed by the trench, performing a second etching process to remove the patterned mask and the modified portion of the first dielectric layer, where etchant of the second etching process further reacts with a part of a remaining portion of the first dielectric layer to cause a volume expansion of the remaining portion of the first dielectric layer, and forming a second conductive feature in the trench.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

As integrated circuit (IC) technologies progress towards smaller technology nodes, there is an increased risk of unwanted coupling between two adjacent conductive components (e.g., gate via and its adjacent source/drain contact). While existing methods for forming gate vias are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor structure, according to one or more aspects of the present disclosure.

FIG. 2 illustrates a fragmentary top view of an exemplary structure to undergo various stages of operations in the method of FIG. 1, according to various aspects of the present disclosure.

FIGS. 3A, 4A, 5A, 6A, 7A, 8A, 9A, 10A, 11A, 12A, 13A, and 14A (FIGS. 3A-14A) illustrate fragmentary cross-sectional views of the structure taken along line A-A′ as shown in FIG. 2 during various fabrication stages in the method of FIG. 1, according to one or more aspects of the present disclosure.

FIGS. 3B, 4B, 5B, 6B, 7B, 8B, 9B, 10B, 11B, 12B, 13B, and 14B (FIGS. 3B-14B) illustrate fragmentary cross-sectional views of the structure taken along line B-B′ as shown in FIG. 2 during various fabrication stages in the method of FIG. 1, according to one or more aspects of the present disclosure.

FIGS. 15A, 16A, 17A, and 18A (FIGS. 15A-18A) illustrate fragmentary cross-sectional views of an alternative structure taken along line A-A′ as shown in FIG. 2 during various fabrication stages in the method of FIG. 1, according to one or more aspects of the present disclosure.

FIGS. 15B, 16B, 17B, and 18B (FIGS. 15B-18B) illustrate fragmentary cross-sectional views of the alternative structure taken along line B-B′ as shown in FIG. 2 during various fabrication stages in the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

IC manufacturing process flow may be typically divided into three categories: front-end-of-line (FEOL) processes, middle-end-of-line (MEOL) processes, and back-end-of-line (BEOL) processes. FEOL processes generally encompasses processes related to fabricating IC devices, such as transistors. For example, FEOL processes may include forming isolation features, gate structures, and source/drain features. Source/drain feature(s) may refer to a source or a drain, individually or collectively dependent upon the context. MEOL processes generally encompasses processes related to fabricating contacts to conductive features of the IC devices, such as gate vias to the gate structures and/or source/drain contacts to the source/drain features. BEOL processes generally encompasses processes related to fabricating a multi-layer interconnect structure that interconnects IC features fabricated by FEOL and MEOL process, thereby enabling operation of the IC devices. Features fabricated by FEOL processes may be referred to as FEOL features. Features fabricated by MEOL processes may be referred to as MEOL features. Features fabricated by BEOL processes may be referred to as BEOL features.

High parasitic capacitance may lead to lower device speed (e.g., RC delays) when distance between two adjacent conductive features reduces to meet design requirements of smaller technology nodes. Low dielectric constant (low-k) materials may be incorporated to reduce parasitic capacitance and thus reduce RC relays. For example, an etch stop layer may include low-k materials. However, some low-k materials are porous and may be more prone to be damaged during etching processes, leading to reduced device performance or reliability issue. For example, during the performing of middle-end-of-line (MEOL) processes, to form a gate via, an etching process may be performed to etch through multiple dielectric layers to form a gate via trench exposing a gate structure, and an ashing process may be performed to remove a mask used during the etching process. The performing of the etching process and ashing process may cause a lateral over-etching of the low-k etch stop layer. In addition, misalignment and overlay problems during the forming of the gate via trench may further aggravate the over-etching, leading to reduced process windows for forming gate vias, and even degraded integrated chip performance. For example, due to overlay problem, the distance between the source/drain contact and the gate via trench may be decreased, and in a cross-sectional view, one side of the gate via trench closer to the source/drain contact may be laterally etched more than the other side of the gate via trench, which may cause the one side of the gate via having a bowing sidewall profile protruding towards the source/drain contact. That is, the gate via formed in the gate via trench may have an asymmetrical profile and includes a main portion extending vertically and an auxiliary portion protruding laterally from the main portion, the auxiliary portion is disposed between the main portion and the source/drain contact. Thus, distance between the resulting gate via and the source/drain contact is undesirably reduced due to the existence of the auxiliary portion. The close proximity between the source/drain contact and gate via may cause undesired leakage between the gate via and the source/drain contact.

The present disclosure provides a method for preventing undesired leakage between the gate via and the source/drain contact by reducing or even eliminating the formation of the unwanted auxiliary portion of the gate via. In an exemplary method, after performing the etching process to form gate via trenches, the ashing process is performed to not only remove the mask, but also react with the low-k etch stop layer to cause a localized volume expansion of the low-k etch stop layer. In an embodiment, the ashing process implements a combination of oxygen and hydrogen. Gate structures exposed by the gate via trenches may undergo oxidization and reduction reactions during the performing of the ashing process. By using a low-k etch stop layer, parasitic capacitance of the structure may be advantageously reduced, and the selection of the etchant used during the ashing process will facilitate the localized volume expansion of the low-k etch stop layer to eliminate the undesired leakage between the gate via and the source/drain contact.

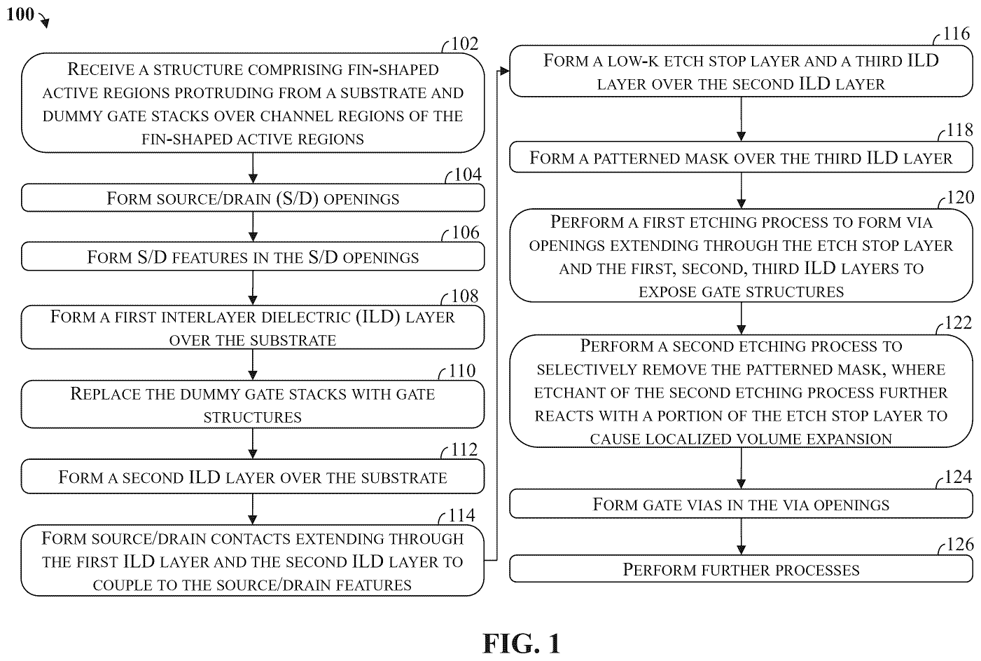

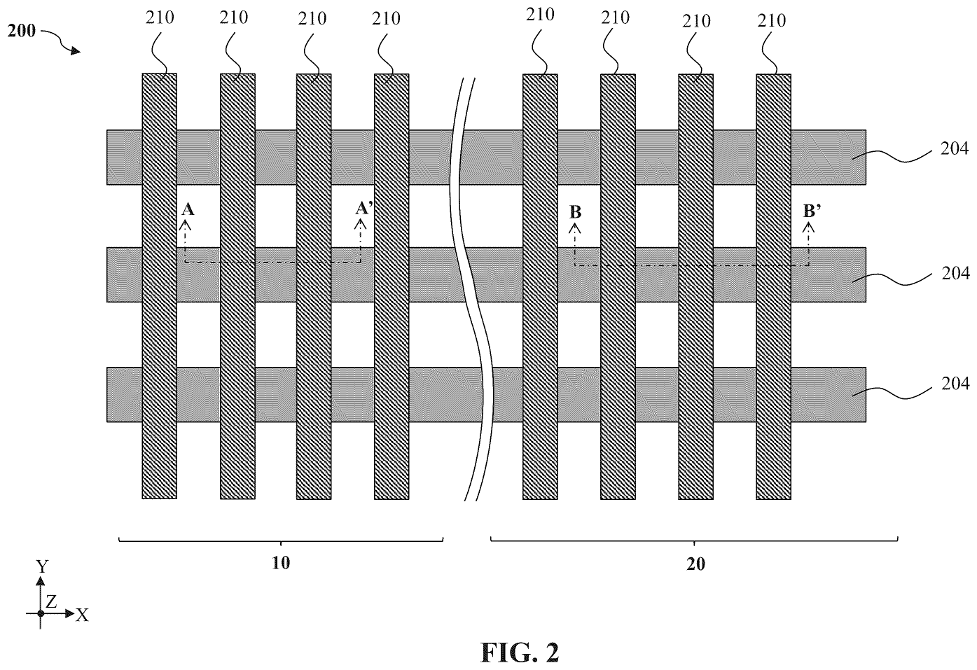

The various aspects of the present disclosure will now be described in more detail with reference to the figures. In that regard, FIG. 1 is a flowchart illustrating method 100 of forming a semiconductor structure 200 according to embodiments of the present disclosure. Method 100 is described below in conjunction with FIGS. 2, 3A-18A and 3B-18B which are fragmentary top/cross-sectional views of the semiconductor structure 200 at different stages of fabrication according to embodiments of method 100. Method 100 is merely an example and is not intended to limit the present disclosure to what is explicitly illustrated therein. Additional steps may be provided before, during and after the method 100, and some steps described can be replaced, eliminated, or moved around for additional embodiments of the method. Not all steps are described herein in detail for reasons of simplicity. For avoidance of doubts, the X, Y and Z directions in FIGS. 2 and 3A-18B are perpendicular to one another and are used consistently throughout the present disclosure. Throughout the present disclosure, like reference numerals denote like features unless otherwise excepted.

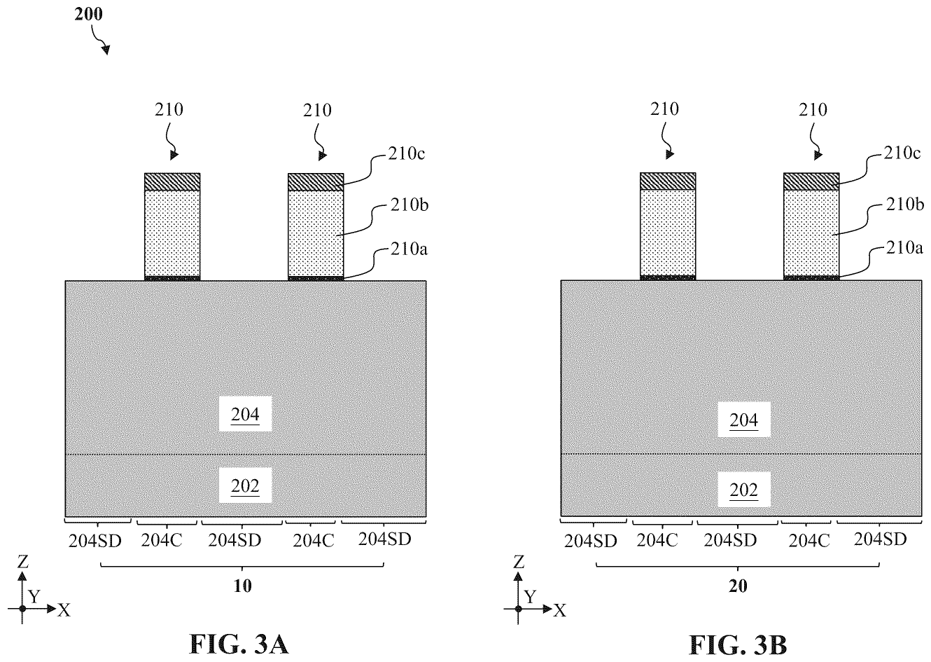

Referring to FIGS. 1, 2, and 3A-3B, method 100 includes a block 102 where a semiconductor structure 200 that includes a first region 10 and a second region 20 is received. In the present disclosure, the first region 10 represents a region that will not undergo misalignment and overlay problems during the formation of gate via, and the second region 20 represents a region that will undergo misalignment and overlay problems during the formation of forming gate via. FIG. 2 depicts a fragmentary top view of the semiconductor structure 200 to undergo various stages of operations in the method of FIG. 1, according to various aspects of the present disclosure. FIG. 3A illustrates a fragmentary cross-sectional view of the semiconductor structure 200 taken along line A-A′ as shown in FIG. 2, and FIG. 3B illustrates a fragmentary cross-sectional view of the semiconductor structure 200 taken along line B-B′ as shown in FIG. 2. As illustrated in FIGS. 3A-3B, the semiconductor structure 200 includes a substrate 202. The substrate 202 may be an elementary (single element) semiconductor, such as silicon (Si) or germanium (Ge) in a crystalline structure; a compound semiconductor, such as silicon carbide (SiC), gallium arsenic (GaAs), gallium phosphide (GaP), indium phosphide (InP), indium arsenide (InAs), and/or indium antimonide (InSb); an alloy semiconductor such as silicon germanium (SiGe), gallium arsenic phosphide (GaAsP), aluminum indium arsenide (AlInAs), aluminum gallium arsenide (AlGaAs), gallium indium arsenide (GalnAs), gallium indium phosphide (GalnP), and/or gallium indium arsenic phosphide (GaInAsP). In one embodiment, the substrate 202 is a silicon (Si) substrate. The substrate 202 may be uniform in composition or may include various layers, some of which may be selectively etched to form fin-shaped active regions (e.g., the fin-shaped active regions 204). The layers may have similar or different compositions, and in various embodiments, some substrate layers have non-uniform compositions to induce device strain and thereby tune device performance. Examples of layered substrates include silicon-on-insulator (SOI) substrates 202. In some such examples, a layer of the substrate 202 may include an insulator such as a semiconductor oxide, a semiconductor nitride, a semiconductor oxynitride, a semiconductor carbide, and/or other suitable insulator materials. Doped regions, such as wells, may be formed in the substrate 202.

Still referring to FIGS. 2 and 3A-3B, the semiconductor structure 200 includes a number of fin-shaped active regions 204 protruding from the substrate 202. The number of fin-shaped active regions 204 depicted in FIGS. 2 and 3A-3B is just an example, the semiconductor structure 200 may include any suitable number of fin-shaped active regions. Each of the fin-shaped active regions 204 extends lengthwise along the X direction and is divided into channel regions 204C overlapped by dummy gate stacks 210 (to be described below) and source/drain regions 204SD adjacent to the channel regions 204C. Source/drain region(s) 204SD may refer to a source region or a drain region, individually or collectively dependent upon the context. Each of the channel regions 204C is disposed between two source/drain regions 204SD along the X direction.

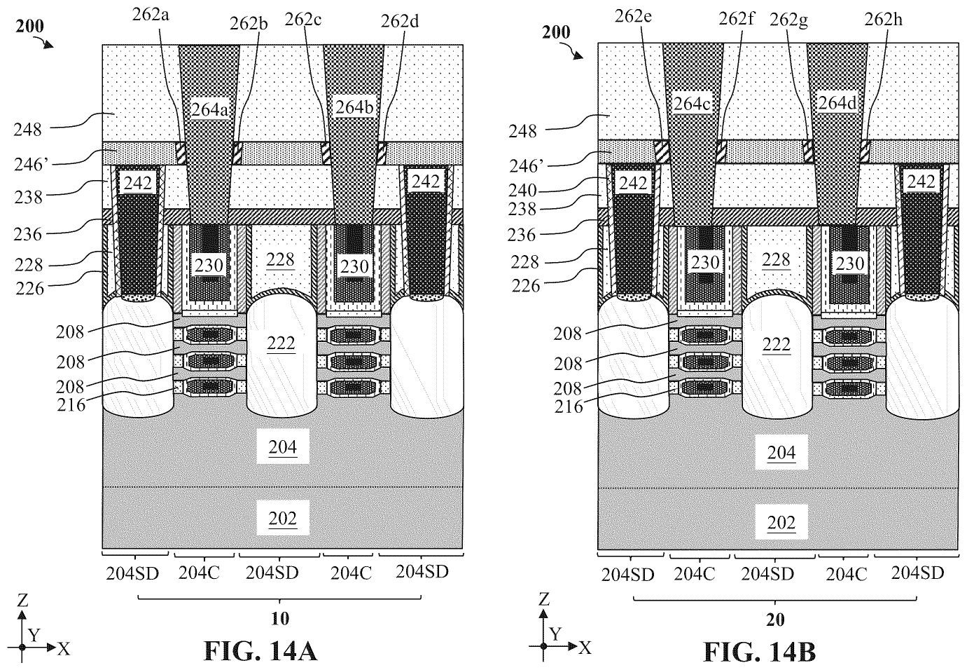

For embodiments in which the semiconductor structure 200 will be fabricated to include FinFETs, each of the fin-shaped active regions 204 may be formed from a top portion of the substrate 202. For embodiments in which the semiconductor structure 200 will be fabricated to include gate-all-around (GAA) transistors, each of the fin-shaped active regions 204 may include a vertical stack (not shown) of alternating semiconductor layers and a portion of the substrate 202. The vertical stack includes a number of channel layers 208 (shown in FIGS. 14A-14B) interleaved by a number of sacrificial layers (not shown). Each of the channel layers 208 may include a semiconductor material such as, silicon, germanium, silicon carbide, silicon germanium, GeSn, SiGeSn, SiGeCSn, other suitable semiconductor materials, or combinations thereof, while each sacrificial layer has a composition different from that of the channel layers 208. In an embodiment, each of the channel layers 208 includes silicon (Si), each of the sacrificial layers includes silicon germanium (SiGe).

The semiconductor structure 200 also includes isolation features (not shown) formed around the fin-shaped active regions 204 to isolate two adjacent fin-shaped active regions 204. The isolation features may include shallow trench isolation (STI) features. In an example process, a dielectric material for the isolation features is first deposited over the semiconductor structure 200 to fill the trenches between the fin-shaped active regions 204. In some embodiments, the dielectric material may include silicon oxide, silicon oxynitride, fluorine-doped silicate glass (FSG), a low-k dielectric, combinations thereof, and/or other suitable materials. In various examples, the dielectric material may be deposited by a CVD process, a flowable CVD (FCVD) process, spin-on coating, and/or other suitable process. The deposited dielectric material is then thinned and planarized, for example by a chemical mechanical polishing (CMP) process, until top surfaces of the fin-shaped active regions 204 are exposed. The planarized dielectric material is further recessed or etched back by a dry etching process, a wet etching process, and/or a combination thereof to form the STI features. Upper portions of the fin-shaped active regions 204 rise above the STI features while lower portions of the fin-shaped active regions 204 remain covered or buried in the STI features. The deposited dielectric material may be a single-layer structure or a multi-layer structure.

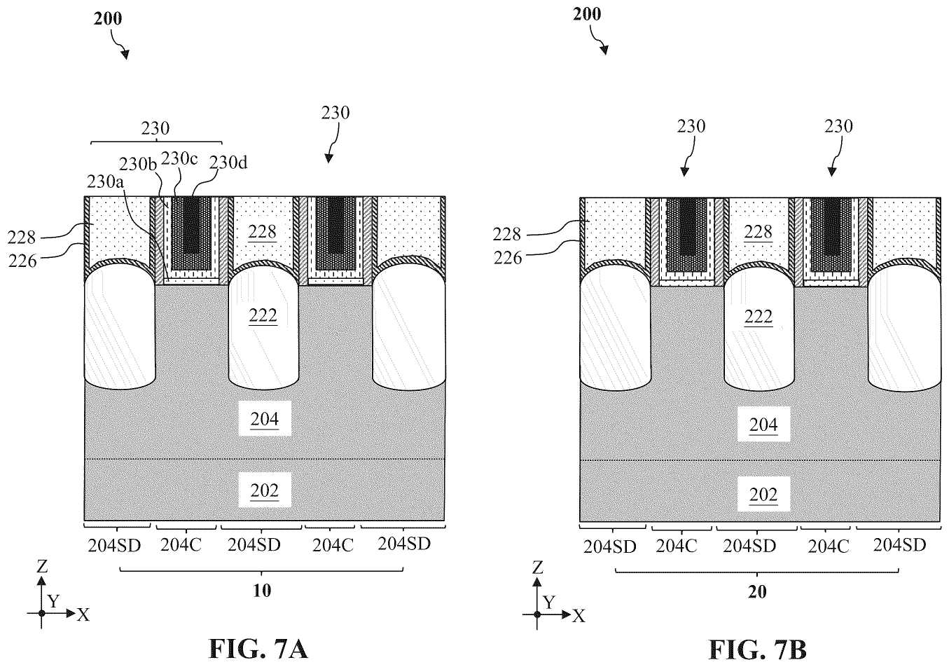

The semiconductor structure 200 also includes dummy gate stacks 210. Each of the dummy gate stacks 210 includes a dummy gate dielectric layer 210a, a dummy gate electrode layer 210b over the dummy gate dielectric layer 210a, and a gate-top hard mask layer 210c over the dummy gate electrode layer 210b. The dummy gate dielectric layer 210a may include silicon oxide. The dummy gate electrode layer 210b may include polysilicon. The gate-top hard mask layer 210c may include silicon oxide, silicon nitride, and/or other suitable materials. Suitable deposition process, photolithography and etching process may be employed to form the dummy gate stacks 210. In this embodiment, a gate replacement process (or gate-last process) is adopted where the dummy gate stacks 210 serve as placeholders for functional gate structures (e.g., gate structures 230 shown in FIGS. 7A-7B). Other processes and configurations are possible. The number of fin dummy gate stacks 210 depicted in FIGS. 2 and 3A-3B is just an example, the semiconductor structure 200 may include any suitable number of dummy gate stacks 210.

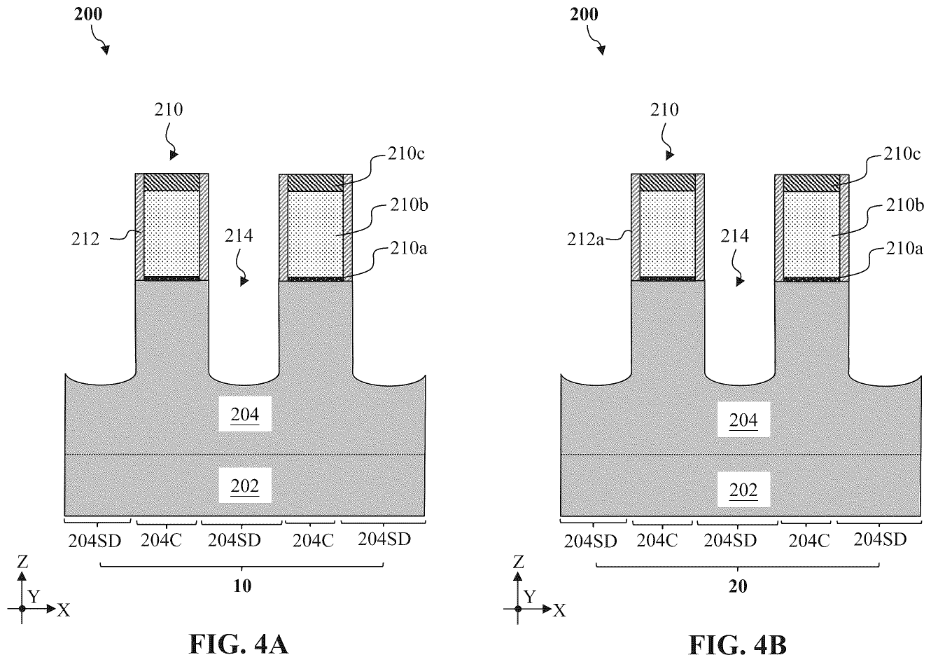

Referring to FIGS. 1 and 4A-4B, method 100 includes a block 104 where source/drain openings 214 are formed. Before forming the source/drain openings, gate spacers 212 are formed to extend along sidewall surfaces of the dummy gate stacks 210. Each of the gate spacers 212 may be a single-layer structure or a multi-layer structure. In an example process, a spacer layer is conformally deposited over the semiconductor structure 200 by atomic layer deposition (ALD), chemical vapor deposition (CVD), or any other suitable deposition process. The term “conformally” may be used herein for ease of description of a layer having substantially uniform thickness over various regions of the semiconductor structure 200. The spacer layer may include silicon oxide, silicon nitride, silicon oxycarbide, silicon oxycarbonitride, silicon carbonitride, metal nitride, other suitable dielectric materials, or combinations thereof. An etching process is performed to remove portions of the spacer layer over top-facing surfaces of the semiconductor structure 200 to form gate spacers 212 extending along sidewalls of the dummy gate stacks 210. The source/drain regions 204SD of the fin-shaped active regions 204 are then recessed to form source/drain openings 214. In some embodiments, the source/drain regions 204SD of the fin-shaped active regions 204 are anisotropically etched by a plasma etch with a suitable etchant. For embodiments in which the semiconductor structure 200 will be fabricated to include GAA transistors, after forming the source/drain openings 214, the sacrificial layers of the vertical stack will be selectively and laterally etched to form inner spacer recesses. Inner spacer features 216 (shown in FIG. 14A-14B) are then formed in the inner spacer recesses. The inner spacer features 216 may include any suitable dielectric material SiN, SiO and/or SiO₂, SiCN, SiOC, SION, SiOCN, a low-k dielectric material, other suitable dielectric material, or combination thereof. The inner spacer features 216 may each be configured as a single-layer structure or a multi-layer structure including a combination of the dielectric materials provided herein. In some embodiments, the inner spacer features 216 have a different composition from that of the gate spacers 212.

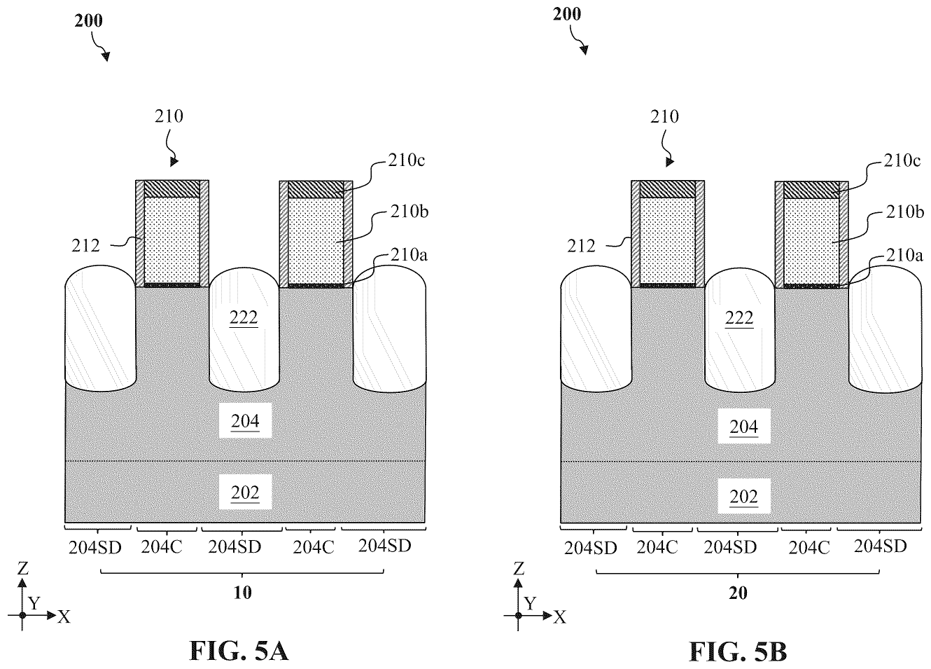

Referring now to FIGS. 1 and 5A-5D, method 100 includes a block 106 where source/drain features 222 are formed in the source/drain openings 214. Source/drain feature(s) 222 may refer to a source or a drain, individually or collectively dependent upon the context. The source/drain features 222 are coupled to the channel regions 204C. Each of the source/drain features 222 may be epitaxially and selectively formed from exposed semiconductor surfaces by using an epitaxial process, such as vapor phase epitaxy (VPE), ultrahigh vacuum chemical vapor deposition (UHV-CVD), molecular-beam epitaxy (MBE), and/or other suitable processes. Example N-type source/drain features may include silicon, phosphorus-doped silicon, arsenic-doped silicon, antimony-doped silicon, or other suitable material and may be in-situ doped during the epitaxial process by introducing an N-type dopant, such as phosphorus, arsenic, or antimony, or ex-situ doped using a junction implant process. Example P-type source/drain features may include germanium, gallium-doped silicon germanium, boron-doped silicon germanium, or other suitable material and may be in-situ doped during the epitaxial process by introducing a P-type dopant, such as boron or gallium, or ex-situ doped using a junction implant process. In some embodiments, each of the N-type source/drain features and the P-type source/drain features may include multiple semiconductor layers with different doping concentrations. The N-type source/drain features and the P-type source/drain features may be formed in any suitable sequential orders.

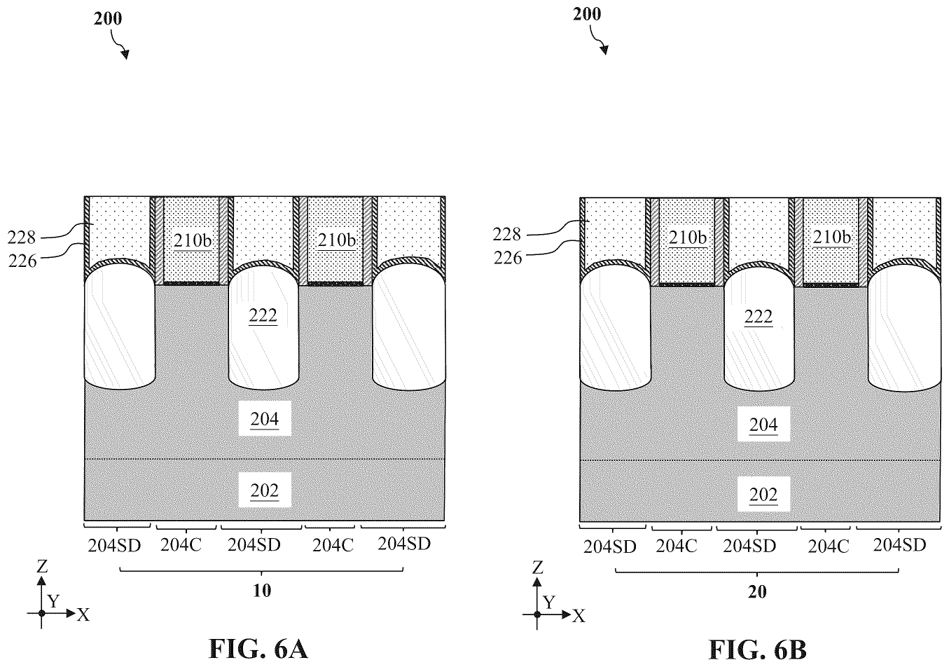

Referring now to FIGS. 1 and 6A-6B, method 100 includes a block 108 where a first interlayer dielectric (ILD) layer 228 is formed over the substrate 202. A contact etch stop layer (CESL) 226 and the first interlayer dielectric (ILD) layer 228 are deposited over the semiconductor structure 200. The CESL 226 may include silicon nitride, silicon oxynitride, and/or other suitable materials and may be formed by ALD, plasma-enhanced chemical vapor deposition (PECVD) process and/or other suitable deposition or oxidation processes. The first ILD layer 228 is deposited by a PECVD process or other suitable deposition technique over the semiconductor structure 200 after the deposition of the CESL 226. The first ILD layer 228 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. A planarization process, such a chemical mechanical polishing (CMP) process may be performed to the semiconductor structure 200 to remove excess materials and expose top surfaces of the dummy gate electrode layers 210b in the dummy gate stacks 210.

Referring now to FIGS. 1 and 7A-7B, method 100 includes a block 110 where the dummy gate stacks 210 are replaced by metal gate structures 230. After exposing the top surfaces of the dummy gate electrode layers 210b in the dummy gate stacks 210, an etching process is implemented to selectively remove the dummy gate electrode layers 210b and the dummy gate dielectric layers 210a of the dummy gate stacks 210 without substantially removing the gate spacers 212 to form gate trenches. Metal gate structures 230 are then formed in the gate trenches in the first region 10 and the second region 20. The formation of the metal gate structure 230 includes forming an interfacial layer 230a over the substrate 202. The interfacial layer 230a may include silicon oxide or other suitable material and may be formed using a suitable method, such as atomic layer deposition (ALD), chemical vapor deposition (CVD), thermal oxidation, or other suitable methods. In an embodiment, the interfacial layer 230a is formed by thermal oxidation. After forming the interfacial layer 230a, a dielectric layer 230b is formed over the semiconductor structure 200 and in the gate trenches. In an embodiment, the dielectric layer 230b is deposited conformally over the semiconductor structure 200. The term “conformally” may be used herein for case of description of a layer having a substantially uniform thickness over various regions. In some embodiments, the dielectric layer 230b is high-k dielectric layer as its dielectric constant is greater than that of silicon dioxide (˜3.9). In some implementations, the dielectric layer 230b may include titanium oxide (TiO₂), tantalum oxide (Ta₂O₅), hafnium silicon oxide (HfSiO₄), zirconium oxide (ZrO₂), zirconium silicon oxide (ZrSiO₂), aluminum oxide (Al₂O₃), zirconium oxide (ZrO), yttrium oxide (Y₂O₃), SrTiO₃ (STO), BaTiO₃ (BTO), BaZrO, aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The dielectric layer 230b and the interfacial layer 230a may be collectively referred to as a gate dielectric layer.

The formation of the metal gate structure 230 also includes forming a gate electrode over the gate dielectric layer. The gate electrode may be a multi-layer structure that includes at least one work function layer 230c and a metal fill layer 230d. By way of example, the at least one work function layer may include titanium nitride (TiN), titanium aluminum (TiAl), titanium aluminum nitride (TiAlN), tantalum nitride (TaN), tantalum aluminum (TaAl), tantalum aluminum nitride (TaAIN), tantalum aluminum carbide (TaAIC), tantalum carbonitride (TaCN), or tantalum carbide (TaC). The metal fill layer 230d may include aluminum (Al), tungsten (W), nickel (Ni), titanium (Ti), ruthenium (Ru), cobalt (Co), platinum (Pt), tantalum silicon nitride (TaSiN), copper (Cu), other refractory metals, or other suitable metal materials or a combination thereof. In various embodiments, the gate electrode may be formed by atomic layer deposition (ALD), physical vapor deposition (PVD), chemical vapor deposition (CVD), e-beam evaporation, or other suitable process. In various embodiments, a planarization process, such as a chemical mechanical polishing (CMP) process, may be performed to remove excess materials over the first ILD layer 228 to provide a substantially planar top surface and facilitate the performing of further processes.

For embodiments in which the semiconductor structure 200 will be fabricated to form GAA transistors, before forming the metal gate structures 230, method 100 further removes the sacrificial layers from the vertical stack during a sheet (or wire) formation process, thereby forming openings (not depicted) between the channel layers 208 (shown in FIGS. 14A-14B). In the present embodiments, the sheet formation process selectively removes the sacrificial layers without removing, or substantially removing, the channel layers 208. The metal gate structures 230 are further configured to wrap around the channel layers 208.

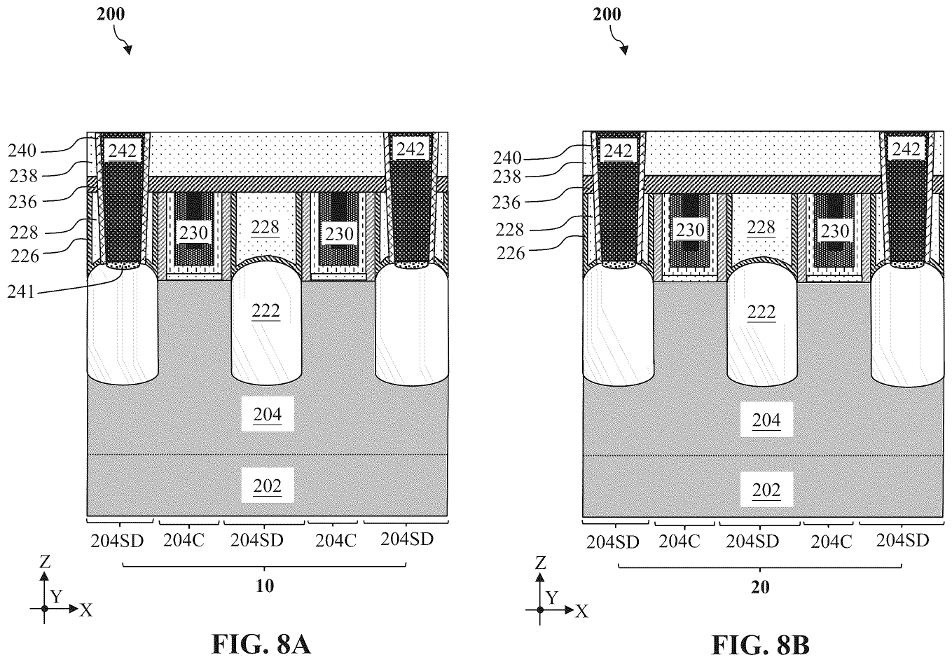

Referring now to FIGS. 1 and 8A-8B, method 100 includes a block 112 where a second interlayer dielectric (ILD) layer 238 is formed over the substrate 202. After forming the metal gate structures 230, an etch stop layer 236 is formed over the first interlayer dielectric (ILD) layer 228. The etch stop layer 236 may include silicon nitride, silicon oxynitride, and/or other suitable materials and may be formed by ALD, plasma-enhanced chemical vapor deposition (PECVD) process and/or other suitable deposition or oxidation processes. In an embodiment, the etch stop layer 236 includes silicon nitride. The composition of the etch stop layer 236 may be the same as or different from the composition of the CESL 226. The formation of the etch stop layer 236 may facilitate the formation of gate vias over the metal gate structures 230 during subsequent fabrication process. The second ILD layer 238 is deposited over the etch stop layer 236 by a PECVD process or other suitable deposition technique over the semiconductor structure 200. The second ILD layer 238 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

Still referring to FIGS. 1 and 8A-8B, method 100 includes a block 114 where source/drain contacts 242 are formed to extend through the first ILD layer 228 and the second ILD layer 238 to couple to the source/drain features 242. In an embodiment, a patterned mask (not shown) is formed over the second ILD layer 238. While using the patterned mask as an etch mask, an etching process is performed to form S/D contact trenches extending through the multiple dielectric layers (e.g., the first and second ILD layers 228 and 238, the CESL and the etch stop layer 226 and 236) and exposing the source/drain features 222. After forming the S/D contact trenches, a dielectric barrier layer 240 is formed to extend along a sidewall surface of each of the S/D contact trenches. In some embodiments, the dielectric barrier layer 240 is formed to enhance isolation between an S/D contact 242 and its adjacent gate structure 230. In an exemplary process, to form the dielectric barrier layer 240, a dielectric material layer is deposited over the semiconductor structure 200, including in the S/D contact trench, and is then etched back to only cover sidewalls of the S/D contact trenches and expose the source/drain features 222. The dielectric barrier layer 240 may include silicon nitride or other suitable materials.

After forming the dielectric barrier layers 240, silicide layers 241 and source/drain contacts 242 are formed in the S/D contact trenches. To form the silicide layers 241, a metal precursor (e.g., titanium, tantalum, nickel, cobalt, or tungsten) is deposited over the semiconductor structure 200, including on the exposed surface of the source/drain features 222. An anneal process is then performed to bring about silicidation and/or germinidation between the metal precursor and the exposed semiconductor surfaces. In some embodiments, the unreacted metal precursor is selectively removed after the formation of the silicide layers 241. A conductive layer is then deposited over the semiconductor structure 200, including in the S/D contact trenches and on the silicide layers 261. The conductive layer may include aluminum (Al), copper (Cu), tungsten (W), cobalt (Co), ruthenium (Ru), or molybdenum (Mo) or other suitable materials and may be formed by any suitable deposition processes (e.g., CVD). A planarization process, such as a chemical mechanical polish (CMP) process, may be then performed to remove excess portions of the conductive layer to form the source/drain contact 242. Although not shown, in some embodiments, the source/drain contact 242 may further include a conductive barrier layer (e.g., TiN, TaN, W) extending along sidewall and bottom surfaces of the conductive layer. In an embodiment, each S/D contact 242 includes a barrier layer formed of titanium or titanium nitride extending along sidewall surface and bottom surface of a conductive layer formed of cobalt. In another embodiment, each S/D contact 242 includes a barrier layer formed of tungsten extending along sidewall surface and bottom surface of a conductive layer formed of tungsten deposited by a physical vapor deposition (PVD) process.

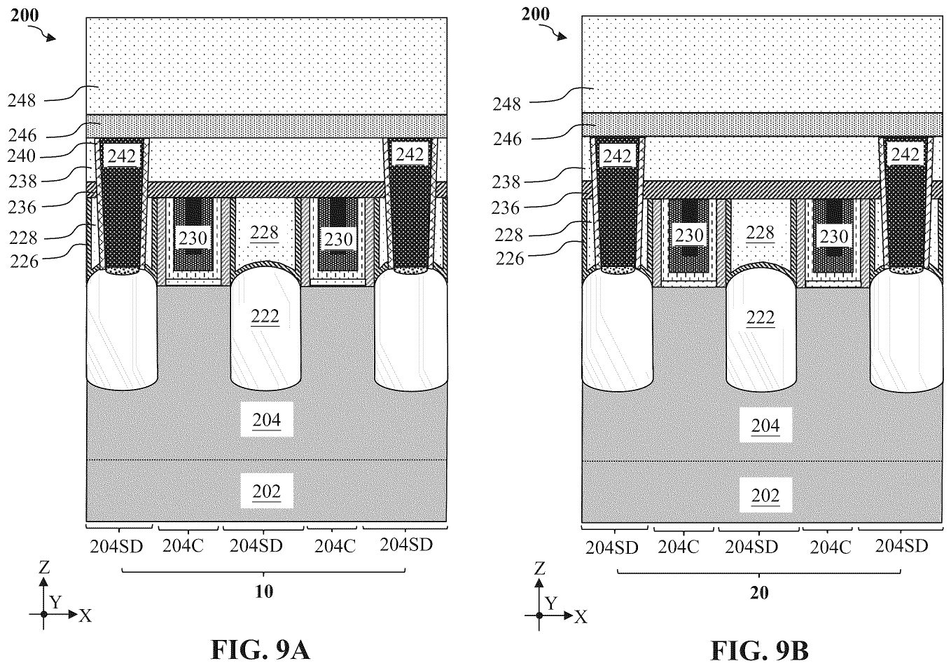

Referring now to FIGS. 1 and 9A-9B, method 100 includes a block 116 where an etch stop layer 246 and a third ILD layer 248 are formed over the second ILD layer 238. After forming the source/drain contacts 242, the etch stop layer 246 is formed on the S/D contacts 242 and the second ILD layer 238. The etch stop layer 246 may be formed by any suitable deposition process (such as CVD, PVD, ALD, high-density plasma chemical vapor deposition (HDPCVD), plasma-enhanced chemical vapor deposition (PECVD), other suitable methods, or combinations thereof). In the present embodiments, to reduce parasitic capacitance, the etch stop layer 246 is a porous low-k material layer, and dielectric constant of the etch stop layer 246 is less than dielectric constant of the CESL 226. For example, the etch stop layer 246 is formed of silicon carbonitride (SiCN). In an embodiment, the CESL 226 is formed of SiN, and nitrogen concentration of the etch stop layer 246 is lower than nitrogen concentration of the CESL 226. After forming the etch stop layer 246, the third ILD layer 248 is formed on the etch stop layer 246. The third ILD layer 248 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials and may be formed by any suitable deposition process (such as CVD, PVD, ALD, HDPCVD, PECVD, other suitable methods, or combinations thereof).

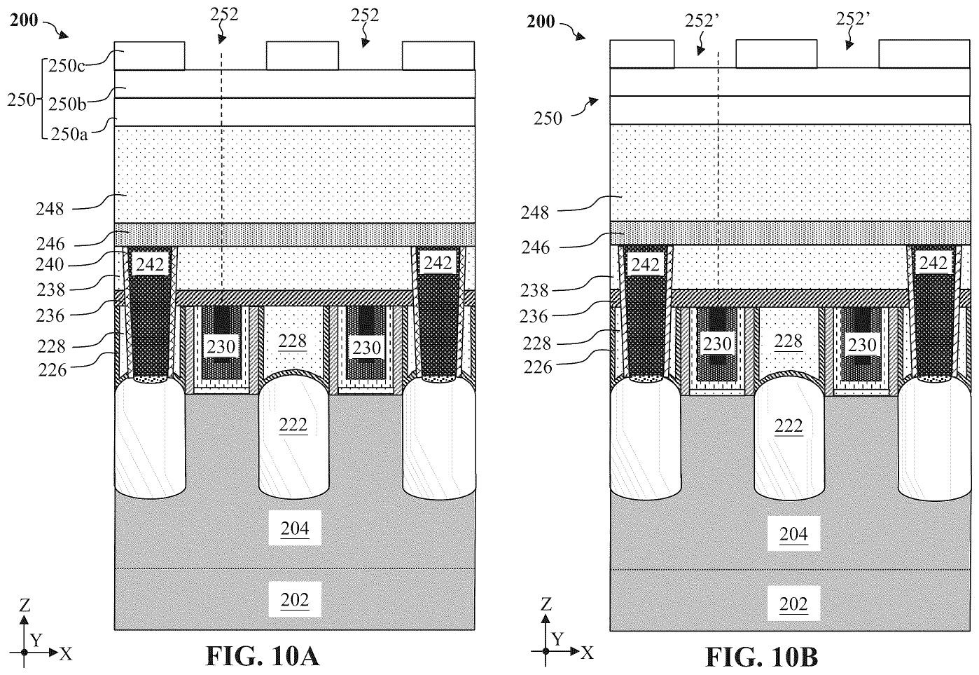

Referring now to FIGS. 1 and 10A-10B, method 100 includes a block 118 where a patterned mask 250 is formed over the third ILD layer 248. In the illustrated embodiment, the patterned mask 250 is a tri-layer structure having a bottom layer 250a, a middle layer 250b over the bottom layer 250a, and a top layer 250c over the middle layer 250b. The top layer 250c may be a photoresist (PR) layer sensitive to light exposure. The middle layer 250b may be an anti-reflective layer to aid in the exposure and focus when patterning the top layer 250c. The middle layer 250b may be a silicon-containing intermediate layer (e.g., spin-on-glass) layer. In an embodiment, the middle layer 250b includes silicon and oxygen. The bottom layer 250a may be an organic film underlayer to provide further anti-reflective properties and etch-durable properties when using the later-formed patterned bottom layer 250a as an etch mask. The bottom layer 250a may include carbon, nitrogen, hydrogen, and/or, oxygen but is free of silicon. In some embodiments, the bottom layer 250a includes a bottom anti-reflection coating (BARC) layer.

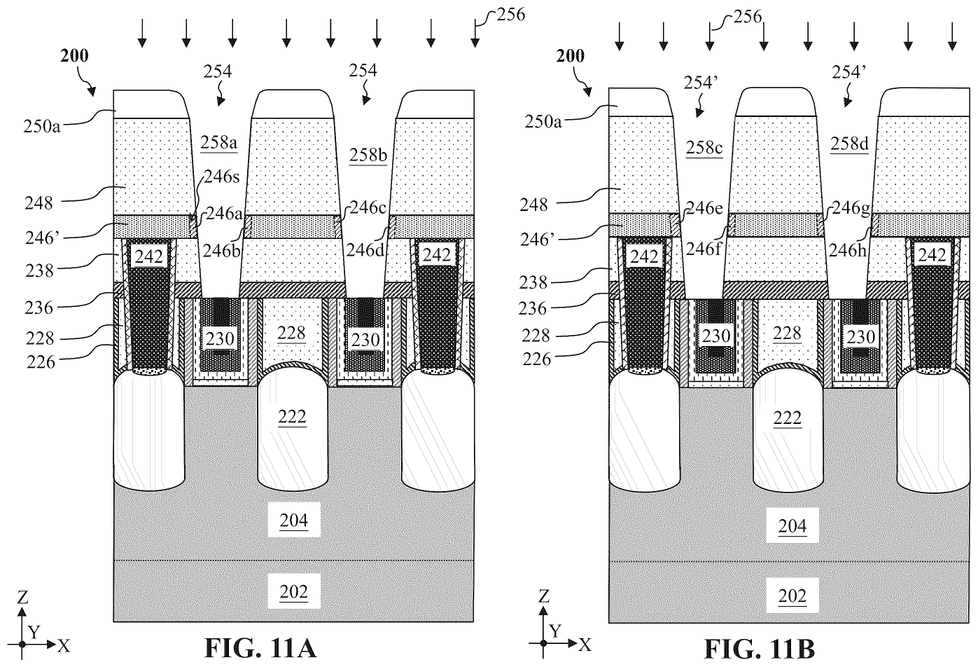

In an exemplary process, with reference to FIGS. 10A-10B, after forming the mask 250 over the substrate 200, the top layer 250a of the mask 250 is patterned to form one or more openings 252 and 252′ over the gate structures 230. The opening(s) 252 is formed in the first region 10, and the opening(s) 252′ is formed in the second region 20. In this embodiment, the openings 252 in the first region 10 are formed without substantially undergoing misalignment and overlay problems, while the openings 252′ in the second region 20 undergo misalignment and overlay problems. For example, a distance between a center line of the opening 252 and a center line (represented by a dashed line in FIG. 10A) of the gate structure 230 thereunder may be less than a distance between a center line of the opening 252′ and a center line (represented by a dashed line in FIG. 10B) of the gate structure 230 thereunder. While using the patterned top layer 250c as an etch mask, an etching process is performed to pattern the middle layer 250b and the bottom layer 250a by transferring the pattern of the top layer 250c to the middle layer 250b and the bottom layer 250a. The patterned bottom layer 250a includes openings 254 (shown in FIG. 11A) in the first region 10 and openings 254′ (shown in FIG. 11B) in the second region 20. After patterning the bottom layer 250a, the top layer 250c and the middle layer 250b may be selectively removed, and the patterned bottom layer 250a remains over the third ILD layer 248.

Referring now to FIGS. 1 and 11A-11B, method 100 includes a block 120 where a first etching process 256 is performed to form via openings (e.g., via openings 258a-258d) extending through the ILD layers 228, 238, 248 and the etch stop layers 236 and 246 to expose the gate structures 230. While using the patterned bottom layer 250a as an etch mask, the first etching process 256 is performed to form the via openings 258a and 258b in the first region 10 and the via openings 258c and 258d in the second region 20. In an embodiment, the first etching process 256 may be a dry etch that implements a fluorine-containing gas (e.g., CF₄, SF₆, CH₂F₂, CHF₃, and/or C₂F₆), other suitable gases and/or plasmas, and/or combinations thereof. Radicals and ions in the plasma of the first etching process 256 may modify portions of the etch stop layer 246 adjacent to the via openings 258a-258d. More specifically, in the cross-sectional views represented by FIGS. 11A and 11B, the etch stop layer 246 includes a modified region 246a and a modified region 246b adjacent to the via opening 258a in the first region 10, a modified region 246c and a modified region 246d adjacent to the via opening 258b in the first region 10, a modified region 246e and a modified region 246f adjacent to the via opening 258c in the second region 20, and a modified region 246g and a modified region 246h adjacent to the via opening 258d in the second region 20. The modified regions 246a-246h may be referred to as etchant modified dielectric features 246a-246h respectively. For embodiments in which the etchant includes a fluorine-containing gas, the modified regions 246a-246h may also be referred to as fluorine-doped dielectric features 246a-246h (e.g., SiCN:F). As described above, the etch stop layer 246 is a porous low-k dielectric layer and may be slightly etched during etching processes (e.g., the first etching process 256). Byproduct (e.g., polymer) of the first etching process 256 may refill the recesses formed due to the slightly etch of the etch stop layer 246. Thus, in some embodiments, the modified regions 246a-246h may also include byproduct (e.g., polymer) of the first etching process 256.

In this illustrated embodiment, the formation of the via openings 258a and 258b in the first region 10 does not undergo significant misalignment or overlay issues, and the formation of the via openings 258c and 258d in the second region 20 undergoes misalignment and/or overlay issues. As a result, a distance between the via opening 258c and its adjacent source/drain contact 242 is less than a distance between the via opening 258a/258b/258d and its respective adjacent source/drain contact 242. Due to the reduced distance, the source/drain contact 242 adjacent to the via opening 258c may tug on more radicals and/or ions in the plasma of the first etching process 256 than other source/drain contacts 242 do, thereby causing modified region 246e to have a width greater than a width of any other modified regions 246a-246d and 246f-246h. In an example, each of the modified regions 246a-246d and 246f-246h spans a width W1 along the X direction, and the modified region 246e spans a width W2 along the X direction and greater than the width W1. In this illustrated embodiments, each of the via openings 258a-258d has a tapered profile with substantially linear sidewalls. For case of description, unmodified regions of the etch stop layer 246 will be referred to as the etch stop layer 246′.

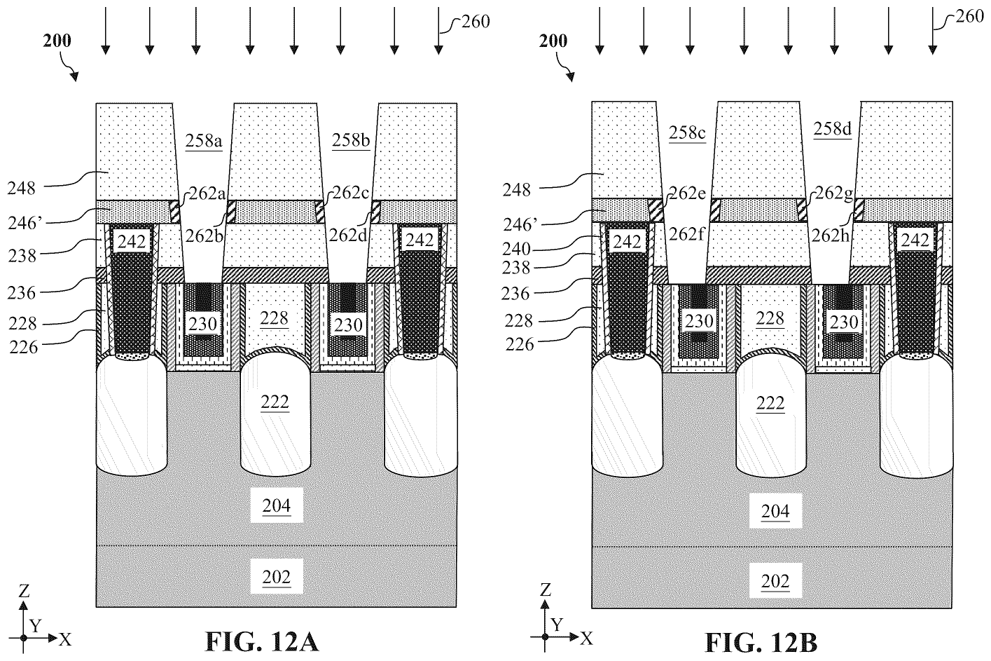

Referring now to FIGS. 1 and 12A-12B, method 100 includes a block 122 where a second etching process 260 is performed to selectively remove the patterned bottom layer 250a. Besides the patterned bottom layer 250a, the second etching process 260 also removes byproduct in the modified regions 246a-2466h without substantially etching the second and third ILD layers 238, 248, unmodified regions of the etch stop layer 246 (i.e., the etch stop layer 246′), and the CESL 236. Since the second etching process 260 removes the patterned bottom layer 250a of the patterned mask 250, the second etching process 260 may also be referred to as an ashing process 260.

Regions 246a-246h include etchant modified regions (e.g., SiCN:F) and are less etch-resistant than the unmodified regions (e.g., SiCN) of the etch stop layer 246 (i.e., the etch stop layer 246′), and the performing of the second etching process 260 also removes the modified regions 246a-246h. That is, sidewalls (e.g., sidewall 246s shown in FIG. 11A) of the etch stop layer 246′ will be exposed by the gate via openings 258a-258d. In other words, the removal of the modified regions 246a-246h will lead to laterally enlarged via openings 258a-258d. As a result, if left unattended, leakage risk between the source/drain contacts 242 and the gate vias that will be formed in the enlarged via openings 258a-258d will be increased, especially the leakage risk between the source/drain contact 242 and the gate via that would be formed in the via opening 258c.

In the present disclosure, to reduce the leakage risk between the source/drain contacts 242 and the adjacent gate vias, etchant of the second etching process 260 is further selected to react with the exposed sidewalls of the etch stop layer 246′ to cause localized volume expansion to fill the recesses previously occupied by the modified regions 246a-246g. The reaction between the exposed sidewalls of the etch stop layer 246′ and etchant of the second etching process 260 forms dielectric features 262a, 262b, 262c, 262d, 262e, 262f, 262g, and 262h adjacent to the via openings 258a-258d. More specifically, the dielectric features 262a and 262b are formed adjacent to the via opening 258a, the dielectric features 262c and 262d are formed adjacent to the via opening 258b, the dielectric features 262e and 262f are formed adjacent to the via opening 258c, and the dielectric features 262g and 262h are formed adjacent to the via opening 258d. In an embodiment, the second etching process 260 is a plasma etching process that implements an oxygen-based gas (e.g., O₂), other suitable gases, and/or combinations thereof. For embodiments in which the etch stop layer 246′ includes silicon carbonitride (SiCN), the dielectric features 262a, 262b, 262c, 262d, 262e, 262f, 262g, and 262h each include silicon oxycarbonitride (SiOCN). The silicon carbonitride etch stop layer 246′ may be oxidized in an outside-in manner, resulting in a silicon oxycarbonitride dielectric features 262a, 262b, 262c, 262d, 262e, 262f, 262g, and 262h and volume expansion of the etch stop layer 246′. The formation of the dielectric features 262a, 262b, 262c, 262d, 262c, 262f, 262g, and 262h and the volume expansion may substantially fill the recesses previously filled by the modified regions 246a-246g. In other words, after the performing of the second etching process 260, unreacted portions of the etch stop layer 246′ is separated from the via openings 258a-258d by the dielectric features 262a-262h, and the via openings 258a-258d after the performing of the second etching process 260 have substantially linear sidewalls. Since the etch stop layer 246′ is disposed vertically between the second ILD layer 238 and the third ILD layer 248 that do not react with oxygen, each of the dielectric features 262a, 262b, 262c, 262d, 262c, 262f, 262g, and 262h is confined to have a height substantially equal to a thickness of the etch stop layer 246′. That is, top surface and bottom surface of each of the dielectric features 262a, 262b, 262c, 262d, 262c, 262f, 262g, and 262h are coplanar with top surface and bottom surface of etch stop layer 246′ respectively. Each of the dielectric features 262a, 262b, 262c, 262d, 262f, 262g spans a width W1′ along the X direction, and the dielectric feature 262e may span a width W2′ along the X direction and greater than the width W1′. In an embodiment, the dielectric feature 262e is in direct contact with the dielectric barrier layer 240 thereunder. In an embodiment, the dielectric feature 262h is vertically overlapped with the gate structure 230 exposed by the via opening 258d. In an embodiment, when viewed from top, the gate via 264c is surrounded by a dielectric feature (e.g., (e.g., dielectric features 262e and 262f) having a ring shape with a non-uniform width.

For embodiments in which the etchant of the second etching process 260 includes oxygen, top surfaces of the gate structures 230 exposed in the via openings 258a-258d will be oxidized. For example, a top portion of the work function layer 230c will be oxidized to form a first metal oxide layer, and a top portion of the metal fill layer 230d will be oxidized to form a second metal oxide layer. In embodiments where the work function layer 230c includes titanium nitride (TiN), the first metal oxide layer may include titanium oxynitride (TiON). In embodiments where the metal fill layer 230d includes tungsten, the second metal oxide layer may include tungsten oxide. In an embodiment, to remove the first and second metal oxide layers without substantially reducing volume of the gate structures 230 and disadvantageous affecting a contact resistance Rc, etchant of the second etching process 260 further includes hydrogen. Hydrogen will react with the first and second metal oxide layers to form metal compound or metal. For example, the reduction reactions include: H₂+TiON→TIN+H₂O, and/or H₂+WOₓ→W+H₂O. The reduction reaction between the metal oxides and hydrogen will form conductive metal compound or metal (e.g., TiN or W). That is, contact resistance Rc and volume of the gate structures 230 will not be substantially affected by the performing of the second etching process 260. In embodiments where the etchant of the second etching process 260 includes both oxygen and hydrogen, the performing of the second etching process 260 realizes at least two functions: selectively removing the patterned bottom layer 250a and byproduct of the first etching process and obtaining localized volume expansion of the etch stop layer 246′ reduce leakage risk without substantially affecting volumes of the gate structures 230 exposed by the via openings 258a-258d. In an embodiment, a ratio of a flow rate of hydrogen to a total flow rate of hydrogen and oxygen in the second etching process 260 is about 10% to about 40%. If the ratio is less than 10%, the reduction reaction between the metal oxide layers and hydrogen may not complete, disadvantageously affecting the contact resistance between gate structures 230 and the gate vias formed thereon; if the ratio is greater than about 40%, the oxidization reaction between the etch stop layer 246′ and oxygen may not complete, and leakage window between the gate vias and the source/drain contacts may not be effectively changed.

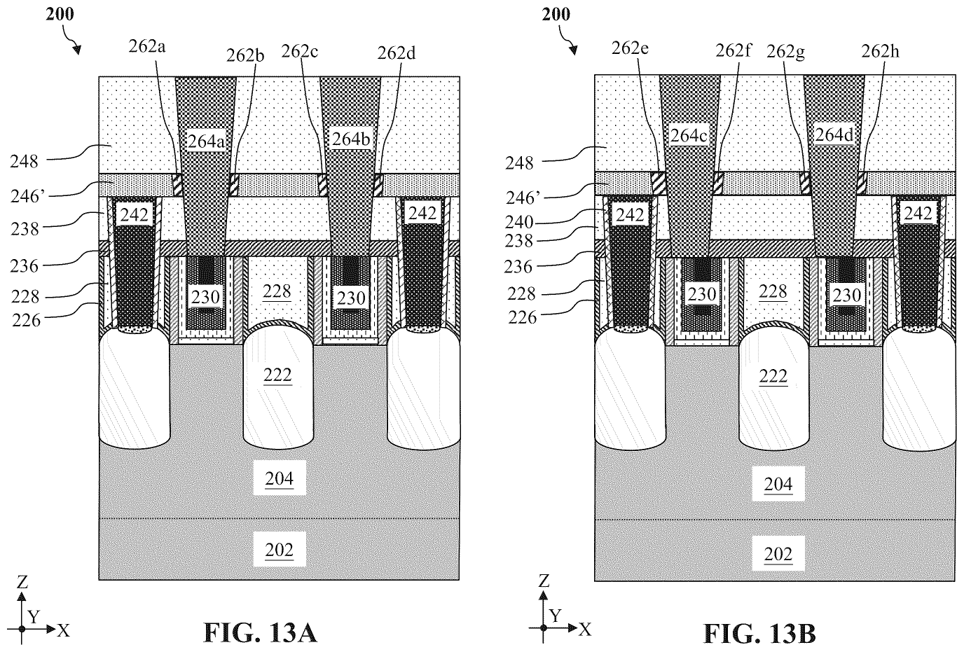

Referring now to FIGS. 1 and 13A-13B, method 100 includes a block 124 where gate vias 264a-264d are formed in the via openings 258a-258d respectively. After the performing of the second etching process 260 and after forming the dielectric features 262a-262h, gate vias 264a-264d are then formed over the gate structures 230 and in the via openings 258a-258d respectively. In an example process, a barrier layer (not explicitly shown) is conformally deposited over the semiconductor structure 200. The barrier layer may include a metal or a metal nitride, such as titanium, titanium nitride, tantalum, tantalum nitride, cobalt nitride, nickel, tungsten, tungsten nitride. Thereafter, a metal fill layer (not explicitly shown) may be deposited over the barrier layer. The metal fill layer may include tungsten, ruthenium, cobalt, nickel, or copper. A CMP process may be followed to remove excessive materials, define the final shapes of the gate vias 264a-264d and provide a planar surface. The gate vias 264a-264d track the shapes of the via openings 258a-258d respectively. In an embodiment, a center line of the gate via 264a substantially aligns with a center line of the gate structure 230 thereunder, a center line of the gate via 264b substantially aligns with a center line of the gate structure 230 thereunder, a center line of the gate via 264c is offset from a center line of the gate structure 230 thereunder, and a center line of the gate via 264a is offset from a center line of the gate structure 230 thereunder. Each of the gate vias 264a-264d is in direct contact with the etch stop layer 236, the second ILD layer 238, the corresponding dielectric features 262a-262b, 262c-262d, 262e-262f, or 262g-262h, and the third ILD layer 248. Each of the gate vias 264a-264d is spaced apart from the etch stop layer 246′ by the corresponding dielectric features 262a-262b, 262c-262d, 262e-262f, or 262g-262h. By converting the modified regions 246a-246h and a portion of the etch stop layer 246′ to dielectric features 264a-264d, the gate vias 264a-264d have substantially linear sidewall profiles that do not protrude towards adjacent source/drain contacts 242. Thus, leakage risk between the gate vias and adjacent source/drain contacts may be advantageously reduced.

Referring to FIG. 1, method 100 includes a block 126 where further processes are performed. After forming the gate vias 264a-264d, further processes are performed to finalize the fabrication of the semiconductor structure 200. For example, additional features such as additional MEOL features and BEOL features (interconnect structure(s)) may be formed over and/or under the semiconductor structure 200. In some embodiments, the interconnect structure may include multiple intermetal dielectric (IMD) layers and multiple metal lines or contact vias in each of the IMD layers. In some instances, the IMD layers and the first ILD layer 228 may share similar composition. The metal lines and contact vias in each IMD layer may be formed of metal, such as aluminum, tungsten, ruthenium, or copper. In some embodiments, the metal lines and contact vias may be lined by a barrier layer to prevent or reduce electro-migration.

In the above embodiments, the semiconductor structure 200 is implemented using fin-type field effect transistors (FinFETs). In some other embodiments, the semiconductor structure 200 may be implemented using GAA transistors. For example, FIGS. 14A-14B illustrate an alternative embodiment in which the fin-shaped active regions 204 include channel layers 208, where the gate structures 230 engage with the channel layers 208 to form GAA transistors.

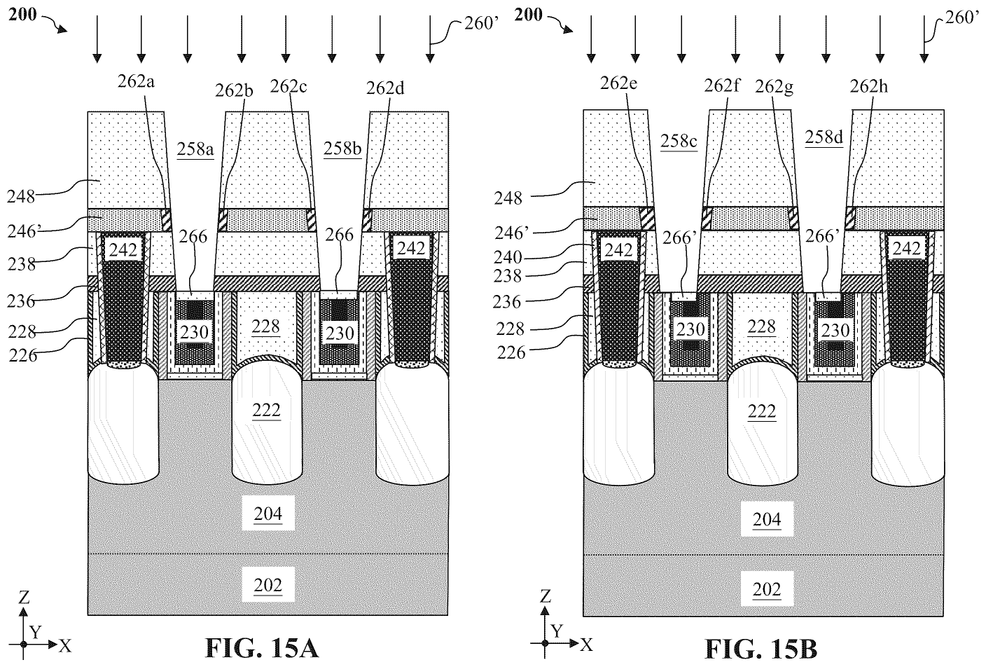

In the above embodiments described with reference to FIGS. 12A-14B, etchant of the second etching process 260 includes a combination of oxygen and hydrogen, and the first and second metal oxide layers formed on the gate structures 230 are converted to conductive materials during the performing of the second etching process 260. In embodiments where reduction reaction(s) did not happen during the performing of the second etching process 260, an additional etching process is performed to selectively remove the first metal oxide layer and the second metal oxide layer. FIGS. 15A-17B depict an alternative embodiment. With reference to FIGS. 15A-15B, after performing the first etching process 256 described with reference to FIGS. 11A-11B, a second etching process 260′ is performed. The etchant of the second etching process 260′ includes oxygen and does not include hydrogen. For example, the etchant of the second etching process 260′ may include a combination of oxygen and nitrogen. Thus, after the performing of the second etching process 260′, the bottom layer 250a is removed, the dielectric features 262a-262h are formed, while the top portions of conductive layers (e.g., work function layer 230c and metal fill layer 230d) of the gate structures 230 are oxidized to form metal oxide layer 266 in the first region 10 and metal oxide layer 266′ in the second region 20. The metal oxide layers 266 and 266′ may include titanium oxynitride, tungsten oxide, a combination thereof, or other possible materials. In some embodiments, due to the overlay and/or misalignment issues, the via openings 258a-258b each expose a larger portion of the gate structure 230 thereunder than the via openings 258c-258d do, and the metal oxide layer 266 in the first region 10 may thus span a width greater than a width of the metal oxide layer 266′ in the second region 20.

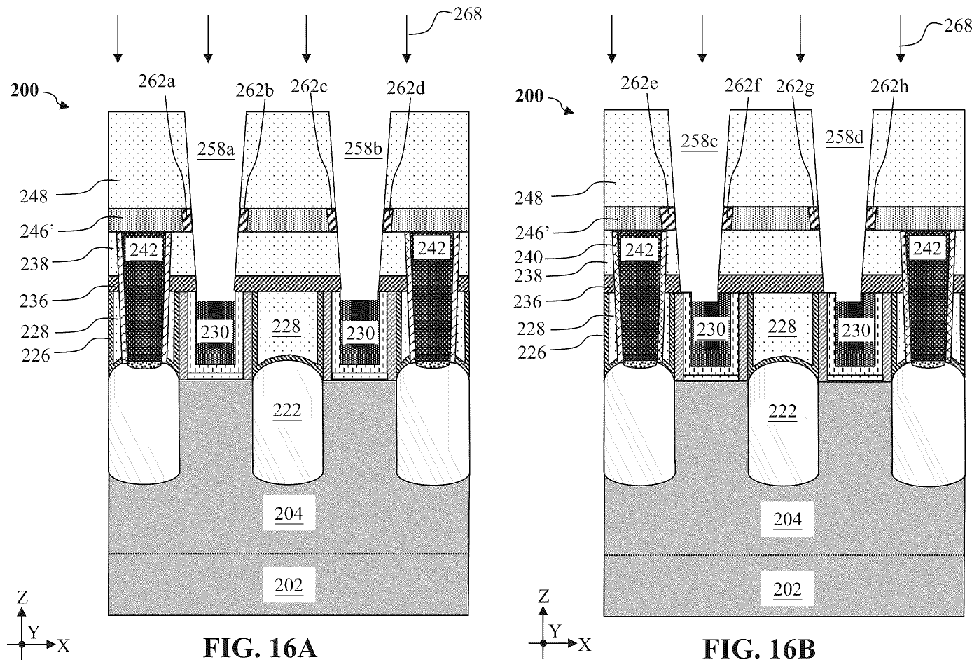

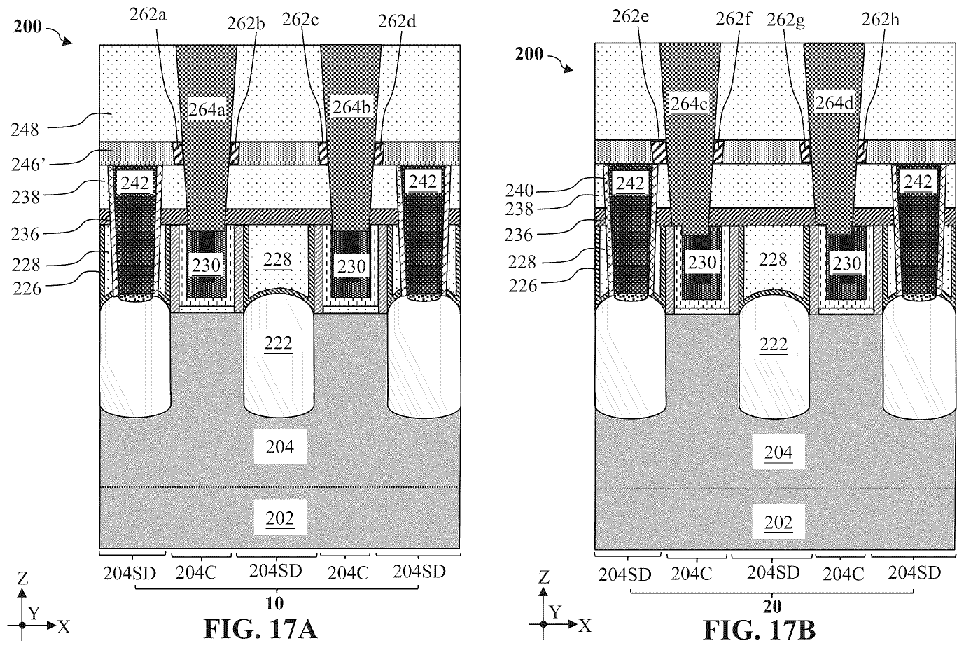

In this alternative embodiment, with reference to FIGS. 16A-16B, after the performing of the second etching process 260′, a third etching process 268 is performed to selectively remove the metal oxide layer 266 and the metal oxide layer 266′ to expose unoxidized portions of conductive layers (e.g., e.g., work function layer 230c and metal fill layer 230d) of the gate structures 230. In an embodiment, due to the selectively removal of the metal oxide layer 266 and the metal oxide layer 266′, top surfaces of the unoxidized portions of conductive layers of the gate structures 230 are lower than a topmost surface of the high-k dielectric layer 230b of the gate structure 230. That is, the via openings 258a-258d are vertically extended. With reference to FIGS. 17A-17B, gate vias 264a-264d are formed in the vertically extended via openings 258a-258d respectively as described above with reference to FIGS. 13A-13B. In this embodiment, the bottommost surface of each of the gate vias 264a-264d may be lower than a topmost surface of the high-k dielectric layer 230b of the gate structure 230.

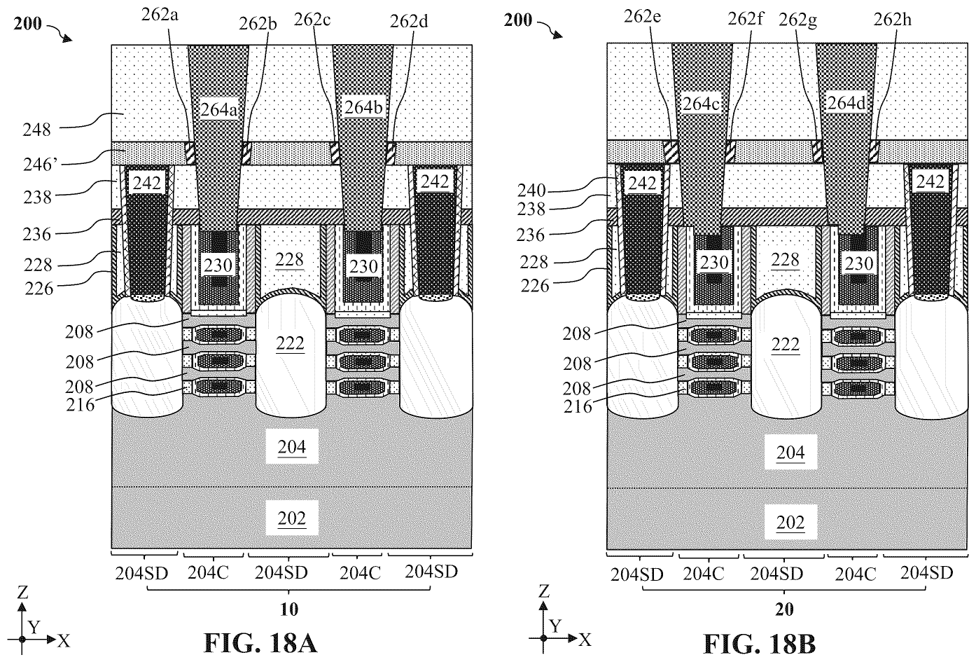

In the above alternative embodiment described with reference to FIGS. 15A-17A and 15B-17B, the semiconductor structure 200 is implemented using FinFETs. In some other embodiments, the semiconductor structure 200 may be implemented using GAA transistors. For example, FIGS. 18A-18B illustrate an embodiment in which the fin-shaped active regions 204 include channel layers 208, where the gate structures 230 engage with the channel layers 208 to form GAA transistors.

Although not intended to be limiting, one or more embodiments of the present disclosure provide many benefits to a semiconductor structure and the formation thereof. For example, parasitic capacitance of the semiconductor structure may be reduced by implementing a low-k etch stop layer. Volume of a low-k dielectric layer may be expanded such that leakage risk between source/drain contacts and adjacent gate vias may be reduced. As such, device performance and reliability of the semiconductor structure may be advantageously improved.

The present disclosure provides for many different embodiments. Semiconductor structures and methods of fabrication thereof are disclosed herein. In one exemplary aspect, the present disclosure is directed to a method. The method includes receiving a structure comprising a gate structure over a channel region, a source/drain feature coupled to the channel region, and a source/drain contact coupled to the source/drain feature, forming a low-k etch stop layer over the source/drain contact, forming a dielectric layer over the low-k etch stop layer, performing an etching process to form a via opening extending through the dielectric layer and the low-k etch stop layer to expose the gate structure, performing a treatment to the structure, thereby oxidizing a portion of the low-k etch stop layer adjacent to the via opening, and forming a gate via in the via opening.

In some embodiments, the method may also include, before the performing of the etching process, forming a patterned mask over the dielectric layer, the patterned mask including an opening directly over the gate structure, wherein the performing of the treatment further removes the patterned mask. In some embodiments, the performing of the treatment may include performing a plasma ashing process implementing an oxygen-containing process gas. In some embodiments, the oxygen-containing process gas may include a combination of oxygen and hydrogen. In some embodiments, the oxygen-containing plasma may include a combination of oxygen and nitrogen. In some embodiments, the performing of the treatment to the structure converts a top portion of the gate structure to a dielectric layer, the method may also include performing an additional etching process to remove the dielectric layer. In some embodiments, the portion of the low-k etch stop layer is a first portion of the low-k etch stop layer, the low-k etch stop layer may also include a second portion disposed between the first portion and the via opening, and the performing of the etching process further converts at least a part of the second portion into an etchant-modified feature, and the performing of the treatment further removes the etchant-modified feature before oxidizing the first portion. In some embodiments, the first portion of the low-k etch stop layer before the performing of the treatment may include silicon carbonitride, and the first portion of the low-k etch stop layer after the performing of the treatment may include silicon oxycarbonitride. In some embodiments, in a cross-sectional view, the oxidized portion of the low-k etch stop layer may include a first part spanning a first width and a second part opposite the first part and spanning a second width, a distance between the first part and the gate structure is less than a distance between the second part and the gate structure, and the first width is greater than the second width. In some embodiments, in a cross-sectional view, the gate via has a substantially symmetric profile, and sidewalls of the gate via are substantially linear.

In another exemplary aspect, the present disclosure is directed to a method. The method includes forming a first dielectric layer over a first conductive feature, forming a second dielectric layer over the first dielectric layer, the first dielectric layer and the second dielectric layer having different compositions, forming a patterned mask over the second dielectric layer, the patterned mask having an opening directly over the first conductive feature, performing a first etching process to form a trench extending through the first dielectric layer and the second dielectric layer to expose a top surface of the first conductive feature, wherein etchant of the first etching process modifies a portion of the first dielectric layer exposed by the trench, performing a second etching process to remove the patterned mask and the modified portion of the first dielectric layer, wherein etchant of the second etching process further reacts with a part of a remaining portion of the first dielectric layer to cause a volume expansion of the remaining portion of the first dielectric layer, and forming a second conductive feature in the trench.

In some embodiments, etchant of the second etching process may include O₂. In some embodiments, etchant of the second etching process may further include H₂. In some embodiments, a ratio of a flow rate of H₂ to a total flow rate of H₂ and O₂ of the second etching process is about 10% to about 40%. In some embodiments, before the performing of the second etching process, the first dielectric layer may include silicon carbonitride, and after the performing of the etching process, the first dielectric layer may include a first region formed of silicon carbonitride and a second region formed of silicon oxycarbonitride. In some embodiments, when viewed from top, the second region of the first dielectric layer resembles a ring with a non-uniform width.

In yet another exemplary aspect, the present disclosure is directed to a semiconductor structure. The semiconductor structure includes a gate structure over a channel region, a source/drain feature coupled to the channel region, a first dielectric layer over the gate structure, a second dielectric layer on the first dielectric layer, and a gate via extending along the first dielectric layer and the second dielectric layer to couple to the gate structure, wherein the first dielectric layer may include a first portion surrounding a part of the gate via and a second portion surrounding the first portion, and a composition of the first portion is different than a composition of the second portion.

In some embodiments, the semiconductor structure may also include a silicide layer on the source/drain feature and a source/drain contact on the silicide layer and disposed under the first dielectric layer. In some embodiments, a width of the first portion of the first dielectric layer is non-uniform. In some embodiments, the first portion of the first dielectric layer may include silicon oxycarbonitride and the second portion of the first dielectric layer may include silicon carbonitride.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a structure comprising:
a gate structure over a channel region,
a source/drain feature coupled to the channel region, and
a source/drain contact coupled to the source/drain feature;
forming a low-k etch stop layer over the source/drain contact;
forming a dielectric layer over the low-k etch stop layer;
performing an etching process to form a via opening extending through the dielectric layer and the low-k etch stop layer to expose the gate structure;
performing a treatment to the structure, thereby oxidizing a portion of the low-k etch stop layer adjacent to the via opening; and
forming a gate via in the via opening.

2. The method of claim 1, further comprising:
before the performing of the etching process, forming a patterned mask over the dielectric layer, the patterned mask including an opening directly over the gate structure,
wherein the performing of the treatment further removes the patterned mask.

3. The method of claim 2, wherein the performing of the treatment comprises performing a plasma ashing process implementing an oxygen-containing process gas.

4. The method of claim 3, wherein the oxygen-containing process gas comprises a combination of oxygen and hydrogen.

5. The method of claim 3, wherein the oxygen-containing plasma comprises a combination of oxygen and nitrogen.

6. The method of claim 5, wherein the performing of the treatment to the structure converts a top portion of the gate structure to a dielectric layer, the method further comprising:
performing an additional etching process to remove the dielectric layer.

7. The method of claim 1,
wherein the portion of the low-k etch stop layer is a first portion of the low-k etch stop layer, the low-k etch stop layer further comprises a second portion disposed between the first portion and the via opening,
wherein the performing of the etching process further converts at least a part of the second portion into an etchant-modified feature, and
wherein the performing of the treatment further removes the etchant-modified feature before oxidizing the first portion.

8. The method of claim 7
wherein the first portion of the low-k etch stop layer before the performing of the treatment comprises silicon carbonitride, and the first portion of the low-k etch stop layer after the performing of the treatment comprises silicon oxycarbonitride.

9. The method of claim 1, wherein, in a cross-sectional view, the oxidized portion of the low-k etch stop layer comprises a first part spanning a first width and a second part opposite the first part and spanning a second width, a distance between the first part and the gate structure is less than a distance between the second part and the gate structure, and the first width is greater than the second width.

10. The method of claim 1, wherein, in a cross-sectional view, the gate via has a substantially symmetric profile, and sidewalls of the gate via are substantially linear.

11. A method, comprising:
forming a first dielectric layer over a first conductive feature;
forming a second dielectric layer over the first dielectric layer, the first dielectric layer and the second dielectric layer having different compositions;
forming a patterned mask over the second dielectric layer, the patterned mask having an opening directly over the first conductive feature;
performing a first etching process to form a trench extending through the first dielectric layer and the second dielectric layer to expose a top surface of the first conductive feature, wherein etchant of the first etching process modifies a portion of the first dielectric layer exposed by the trench;
performing a second etching process to remove the patterned mask and the modified portion of the first dielectric layer, wherein etchant of the second etching process further reacts with a part of a remaining portion of the first dielectric layer to cause a volume expansion of the remaining portion of the first dielectric layer; and
forming a second conductive feature in the trench.

12. The method of claim 11, wherein etchant of the second etching process comprises O₂.

13. The method of claim 12, wherein etchant of the second etching process further comprises H₂.

14. The method of claim 13, wherein a ratio of a flow rate of H₂ to a total flow rate of H₂ and O₂ of the second etching process is about 10% to about 40%.

15. The method of claim 11, wherein before the performing of the second etching process, the first dielectric layer comprises silicon carbonitride, and after the performing of the etching process, the first dielectric layer comprises a first region formed of silicon carbonitride and a second region formed of silicon oxycarbonitride.

16. The method of claim 15, wherein when viewed from top, the second region of the first dielectric layer resembles a ring with a non-uniform width.

17. A semiconductor structure, comprising:
a gate structure over a channel region;
a source/drain feature coupled to the channel region;
a first dielectric layer over the gate structure;
a second dielectric layer on the first dielectric layer; and
a gate via extending along the first dielectric layer and the second dielectric layer to couple to the gate structure,
wherein the first dielectric layer comprises a first portion surrounding a part of the gate via and a second portion surrounding the first portion, and a composition of the first portion is different than a composition of the second portion.

18. The semiconductor structure of claim 17, further comprising:
a silicide layer on the source/drain feature; and
a source/drain contact on the silicide layer and disposed under the first dielectric layer.

19. The semiconductor structure of claim 17, wherein a width of the first portion of the first dielectric layer is non-uniform.

20. The semiconductor structure of claim 17, wherein the first portion of the first dielectric layer comprises silicon oxycarbonitride and the second portion of the first dielectric layer comprises silicon carbonitride.
